(19) United States
(12) Patent Application Publication
(10) Pub. No.: US 2026/0185614 A1
(43) Pub. Date: Jul. 2, 2026

(54) VACUUM VALVE AND SUBSTRATE PROCESSING APPARATUS INCLUDING THE VACUUM VALVE

(71) Applicant: KITZ SCT CORPORATION, Tokyo (JP)

(72) Inventors: Ryosuke HAYASHI, Gunma (JP); Kaito Sakurai, Gunma (JP)

(21) Appl. No.: 19/429,305

(22) Filed: Dec. 22, 2025

(30) Foreign Application Priority Data
Dec. 27, 2024 (JP) 2024-232810

(51) Int. Cl. F16K 3/02; F16K 51/02

(52) U.S. Cl. CPC F16K 3/0281; F16K 51/02

(57) ABSTRACT

A vacuum valve has shutter, a shutter ring that hermetically closes a flow path port by pressing the shutter to an inner wall surface, and a first radial bearing rotatable about a first rotating shaft substantially parallel to a flow path direction to rotate along a guide groove. The vacuum valve also has a second radial bearing rotatable about a second rotating shaft substantially orthogonal to the flow path direction and having an outer circumferential surface arranged closer to the flow path port than a tip face of the first rotating shaft, and an elastic member that exerts a spring-back force on the second radial bearing toward the inner wall surface when the second radial bearing receives a load via the inner wall surface near the flow path port toward the inside of the valve housing in the flow path direction.

### BACKGROUND OF THE INVENTION

### Field of the Invention

The present invention relates to a vacuum valve and a substrate processing apparatus including this vacuum valve and, in particular, to a vacuum valve including a shutter that opens and closes a flow path port of a valve housing and a shutter ring that presses the shutter toward the flow path port and a substrate processing apparatus including this vacuum valve.

### Description of the Related Art

Conventionally, a valve in an exhaust system of a substrate processing apparatus for a semiconductor wafer, liquid-crystal substrate, substrate for a solar cell panel, or the like is provided with a shutter that moves in a substantially L shape to open and close a flow path port of a valve housing.

This shutter is moved in parallel to the flow path port and is pressed by a shutter ring at a position opposed to the flow path port to a flow path port side to close hermetically close the flow path port.

For example, Japanese Unexamined Patent Application Publication (Translation of PCT Application) No. 2022-528162 (hereinafter the patent document)describes a substrate processing apparatus including an exhaust pump for exhausting gas in a substrate processing space of a process chamber to the outside, a first flow path portion coupled to the process chamber to communicate to the substrate processing space, a second flow path portion connected to the exhaust pump, and a valve module arranged between the first flow path portion and the second flow path portion to open and close a flow path where gas flows.

In the valve module described in this patent document, a blade portion (corresponding to the shutter) with its both side portions coupled to a reinforcing frame portion is moved forward and backward by being guided by a guide roller provided to the reinforcing frame portion.

When the blade portion is pressed by a shutoff ring portion (corresponding to the shutter ring) toward the flow path port, the blade portion is relatively moved to the reinforcing frame toward the flow path port, thereby allowing the guide roller provided to the reinforcing frame to keep a predetermined position.

### BRIEF SUMMARY OF THE INVENTION

However, in the substrate processing apparatus described in the patent document, when the apparatus is applied to both vertical orientation installation in which an X direction is set as an up-down direction and horizontal orientation installation in which a Z direction is set as an up-down direction, the orientation of the rotating shaft of the guide roller for guiding the movement of opening/closing the shutter changes to two directions, a vertical direction and a horizontal direction. Thus, for the guide roller, not a thrust bearing supporting only one direction but a radial bearing is used.

That is, in the substrate processing apparatus described in the patent document, when a radial bearing is used for the guide roller to support both vertical and horizontal orientation installations, the guide roller receives a load in an axial direction when the blade portion is pressed by the shutoff ring (corresponding to the shutter ring) toward the flow path port.

Since the radial bearing is weak against the load in the axial direction, durability of the guide roller is decreased in the substrate processing apparatus described in the patent document and, as a result, durability of a movement guide mechanism of the shutter may be decreased.

The present invention was developed to solve the conventional problems, and is to provide a vacuum valve capable of improving durability of the movement guide mechanism of the shutter while being capable of supporting vertical and horizontal orientation installations, and a substrate processing apparatus including the vacuum valve.

To achieve the above-described object, the invention according to claim 1 is directed to a vacuum valve having a shutter provided in a valve housing so as to be movable between a close position and an open position, the close position being opposed in parallel to a flow path port formed in the valve housing on a downstream side in a flow path direction and the open position being for opening a front of the flow path port, and a shutter ring provided in the valve housing so as to be able to advance and retreat along the flow path direction, the shutter ring hermetically closing the flow path port by pressing the shutter to an inner wall surface of the valve housing with a tip surface when the shutter is at the close position, the vacuum valve having a first radial bearing provided so as to be rotatable about a first rotating shaft substantially parallel to the flow path direction to rotate along a guide groove provided in the valve housing in parallel to the flow path port, a second radial bearing provided so as to be rotatable about a second rotation shaft substantially orthogonal to the flow path direction and having an outer circumferential surface arranged closer to the flow path port than a tip face of the first rotating shaft of the first radial bearing, and an elastic member that exerts a spring-back force on the second radial bearing toward the inner wall surface when the second radial bearing receives a load via the inner wall surface of the valve housing near the flow path port toward the inside of the valve housing in the flow path direction.

The invention according to claim 2 is directed to the vacuum valve further having a holder having the first rotating shaft, the second rotating shaft, and the elastic member attached thereto, in which the holder is coupled to the shutter so as to be able to elastically advance and retreat via the elastic member in the flow path direction.

The invention according to claim 3 is directed to the vacuum valve, in which the elastic member is provided at each of positions that are symmetric with respect to the second rotating shaft.

The invention according to claim 4 is directed to the vacuum valve, in which the shutter has a substantially rectangular shape, and the holder is provided at each of portions near the four corners of the shutter.

The invention according to claim 5 is directed to the vacuum valve, in which the valve housing has formed therein a first guide groove being a guide groove that guides the first radial bearing in parallel to the flow path port and a second guide groove that guides the second radial bearing in parallel to the flow path port, and the first guide groove and the second guide groove have an amount of play with respect to the first radial bearing and an amount of play with respect to the second radial bearing, respectively, that are adjusted so as to inhibit contact of the first radial bearing with a side surface of the first guide groove in a direction of the first rotating shaft.

The invention according to claim 6 is directed to the vacuum valve, in which the vacuum valve is a circular gate valve.

The invention according to claim 7 is directed to a substrate processing apparatus, in which the vacuum valve according to claim 1 is interposed between an exhaust connecting portion of a chamber that processes a substrate and an exhaust path connected to a vacuum pump.

In the invention according to claim 1, by the first radial bearing that rotates along the guide groove provided in the valve housing in parallel to the flow path port on the downstream side in the flow path direction, the shutter is movably guided between a closed position opposed to the flow path port in parallel to the flow path port and an open position that opens the front of the flow path port. Also, by the second radial bearing, the load of the first radial bearing in the axial direction is received via the inner wall surface near the flow path port of the valve housing as a load toward the inside of the valve housing in the flow path direction. The second radial bearing receives the load of the first radial bearing in a first rotating shaft direction by using the spring-back force by the elastic member in the radial direction (radial direction).

Thus, according to the invention according to claim 1, as the radial bearings capable of supporting both vertical and horizontal orientation installations are applied as bearings for guiding the movement of the shutter, the first radial bearing is prevented from being damaged by the load in the first rotating shaft direction. As a result, both vertical and horizontal orientation installations can be supported, and durability of the movement guide mechanism of the shutter can be improved.

In the invention according to claim 2, the vacuum valve has a holder having the first radial bearing, the second radial bearing, and the elastic member attached thereto.

The holder is coupled to the shutter so as to be able to elastically advance and retreat via the elastic member in the flow path direction. With this, the first radial bearing moves together with the second radial bearing attached to the holder in the flow path direction.

Also, the second radial bearing is arranged closer to the flow path port than the first radial bearing, and the amount of movement in the flow path direction is restricted by using the spring-back force by the elastic member.

Thus, according to the invention according to claim 2, the position of the first radial bearing in the flow path direction can be stabilized, contact with the side surfaces of the guide groove can be suppressed, and durability can be improved.

Furthermore, according to the invention according to claim 2, the first radial bearing, the second radial bearing, and the elastic member can be assembled to the shutter in units of the holder, and assemblability can be improved.

In the invention according to claim 3, the elastic member is provided at each of positions that are symmetric with respect to the second rotating shaft. Thus, the load in the radial direction to be added to the second radial bearing by spring-back forces of the two elastic members can inhibit the second radial bearing from rotating. As a result, the second radial bearing receives the load from the inner wall surface of the valve housing in a balanced manner, and can stably actuate the shutter toward the inside of the valve housing.

In the invention according to claim 4, the shutter has a substantially rectangular shape, and the holder is provided at each of portions near the four corners of the shutter. With this, by the first radial bearing and the second radial bearing provided at the four corners together with the holder, the tilt of the shutter with respect to a posture in parallel to the flow path port is restricted. Thus, the shutter can be moved to open and close as being kept with a stable posture in parallel to the flow path port.

In the invention according to claim 5, the valve housing has formed therein a first guide groove being a guide groove that guides the first radial bearing in parallel to the flow path port and a second guide groove that guides the second radial bearing in parallel to the flow path port. The first guide groove and the second guide groove have an amount of play with respect to the first radial bearing and an amount of play with respect to the second radial bearing, respectively, that are adjusted so as to inhibit contact of the first radial bearing with a side surface of the first guide groove in a direction of the first rotating shaft.

With this, according to the invention according to claim 5, even if the vacuum valve is used for both vertical and horizontal orientation installations, the first radial bearing is prevented from moving to the axial direction to make contact with the side surface of the first guide groove and, as a result, durability of the first radial bearing can be improved.

In the invention according to claim 6, the vacuum valve is a circular gate valve. Thus, with a compact and simple structure, the shutter can be guided by the first radial bearing and the second radial bearing to open and close the circular flow path port.

In the invention according to claim 7, the vacuum valve according to claim 1 is interposed between an exhaust connecting portion of a chamber that processes a substrate and an exhaust path connected to a vacuum pump. With this, effects similar to those by the vacuum valve described above are exerted.

### BRIEF DESCRIPTION OF THE DRAWINGS

FIG. 1 is a schematic structure diagram of a substrate processing apparatus according to an embodiment;

FIG. 2A is a perspective view of a vacuum valve according to the embodiment viewed from an upstream side;

FIG. 2B is a perspective view of the vacuum valve according to the embodiment viewed from a downstream side;

FIG. 3 is a perspective sectional view of a portion near a first radial bearing of the vacuum valve;

FIG. 4 is a drawing of the vacuum valve partially extracted;

FIG. 5 is a sectional view of a portion near an air cylinder of the vacuum valve depicted in FIG. 4;

FIG. 6 is a drawing of the vacuum valve partially extracted with a shutter being in a closed state;

FIG. 7 is an enlarged view of a shutter guide mechanism depicted in FIG. 6;

FIG. 8 is a perspective view of a holder;

FIG. 9A is a drawing for describing a guide relation between a first radial bearing and a second radial bearing, depicting a perspective view of a first guide groove and a second guide groove;

FIG. 9B is a drawing for describing a guide relation between the first radial bearing and the second radial bearing, depicting a sectional view of the first guide groove and the second guide groove;

FIG. 10A is a drawing for describing opening/closing operation of the shutter;

FIG. 10B is a drawing for describing opening/closing operation of the shutter;

FIG. 10C is a drawing for describing opening/closing operation of the shutter;

FIG. 10D is a drawing for describing opening/closing operation of the shutter; FIG. 11A is an enlarged view of a shutter guide mechanism on the lower side depicted in FIG. 10A;

FIG. 11B is an enlarged view of the shutter guide mechanism on the lower side depicted in FIG. 10B;

FIG. 11C is an enlarged view of the shutter guide mechanism on the lower side depicted in FIG. 10C; and

FIG. 11D is an enlarged view of the shutter guide mechanism on the lower side depicted in FIG. 10D.

In the drawings, a direction in which gas in an exhaust system flows, that is, a flow path direction, is indicated by an arrow A, with an upstream side indicated by “U” and a downstream side indicated by “D”.

### DETAILED DESCRIPTION OF THE INVENTION

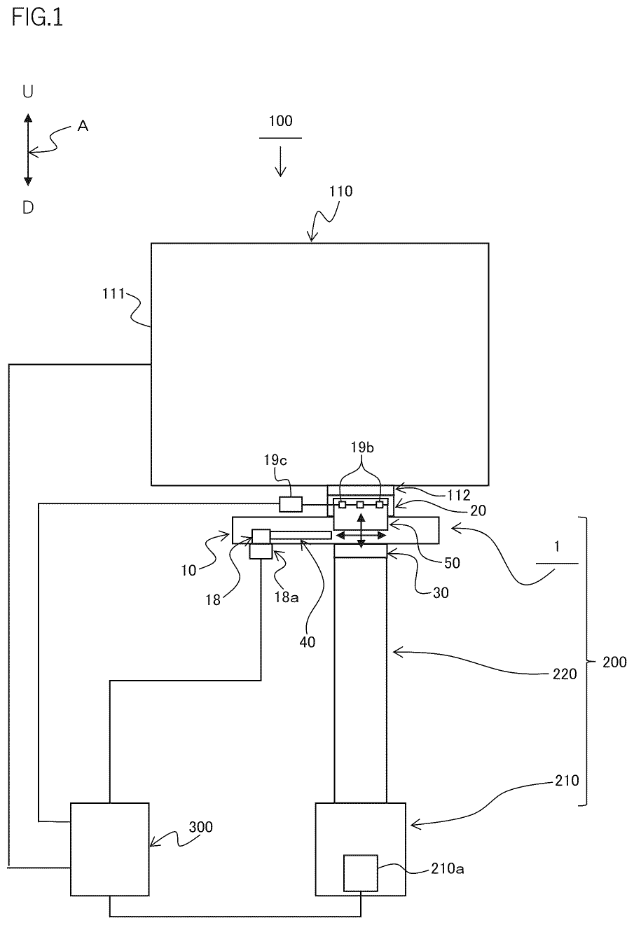

Embodiments of a vacuum valve and a substrate processing apparatus according to the present invention are described in detail below based on FIG. 1 to FIG. 9B.

It is noted that the present disclosure is not limited by the embodiments described below. It is also noted that the drawings are schematic, and the relation in dimension among elements, ratio of each element, and so forth may be different from actual ones. Furthermore, among the drawings, a portion in which the relation in dimension among them and/or the ratio is different may be included.

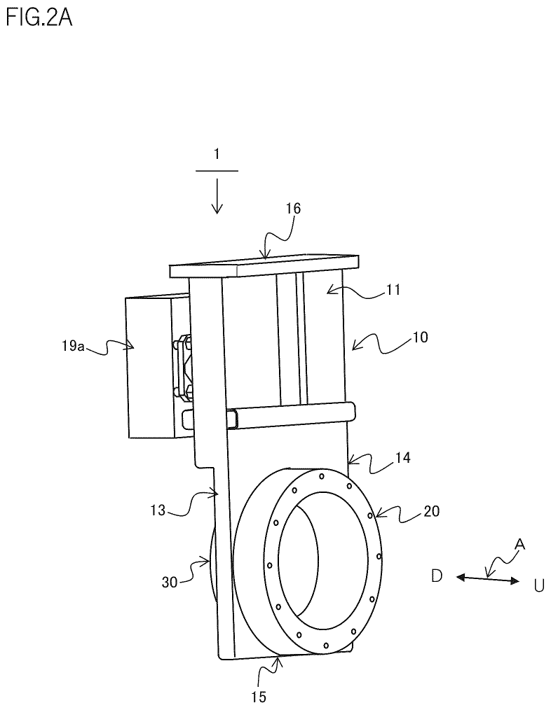

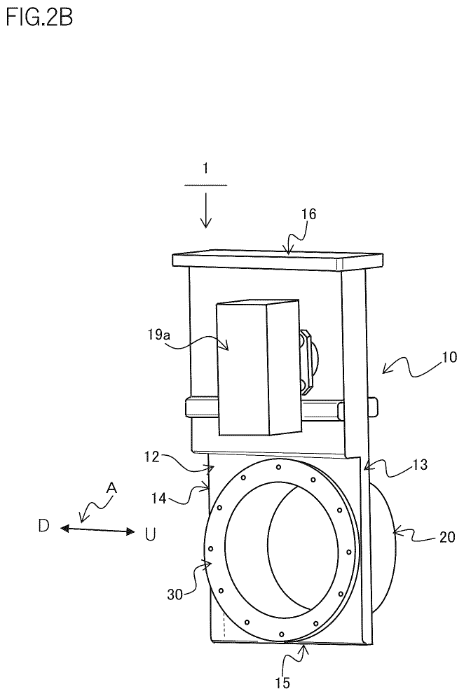

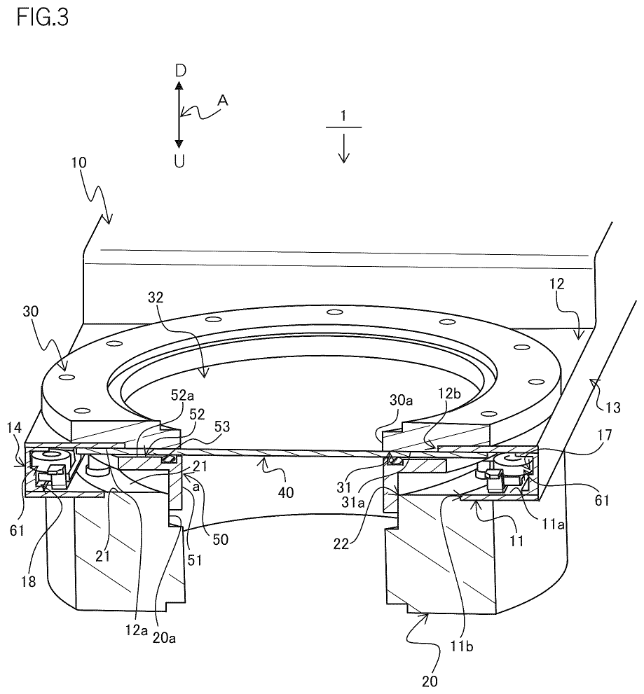

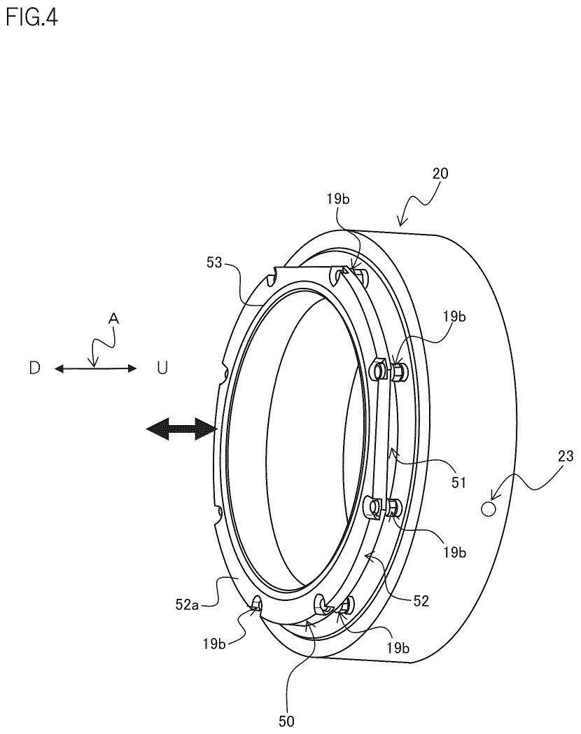

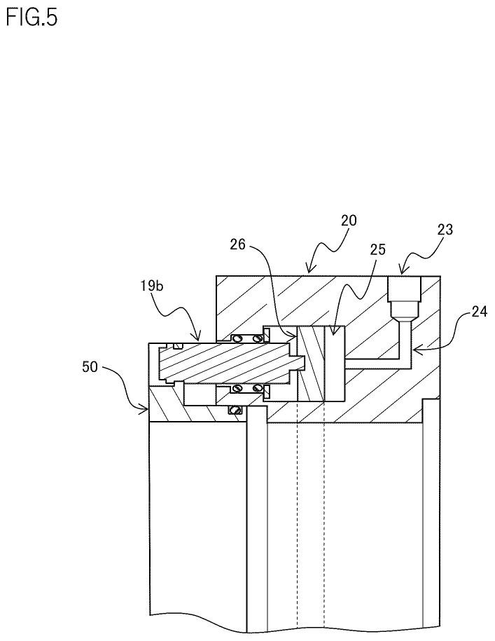

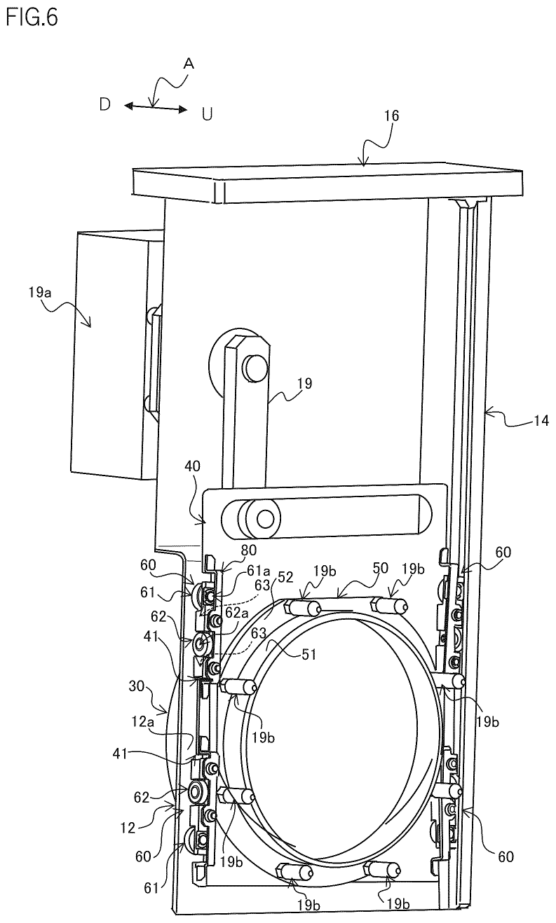

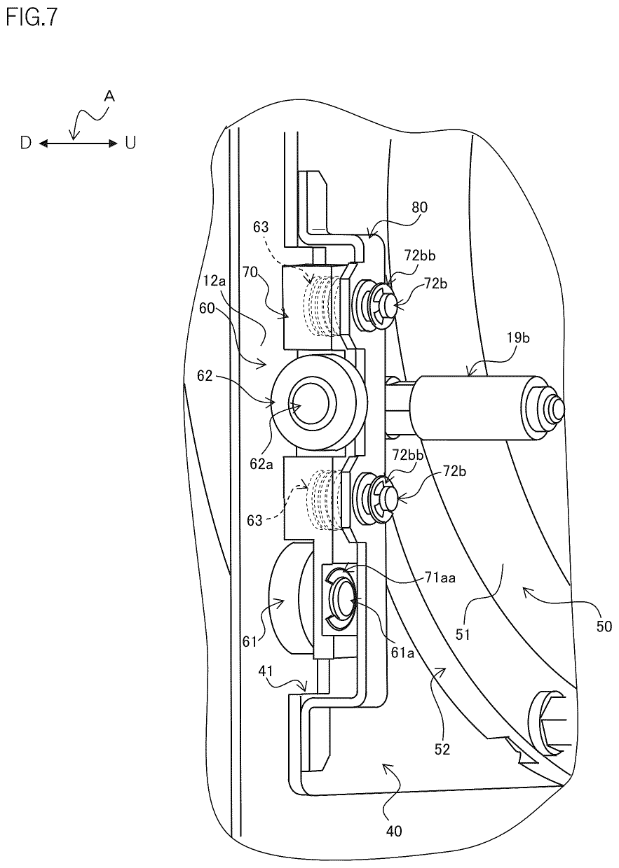

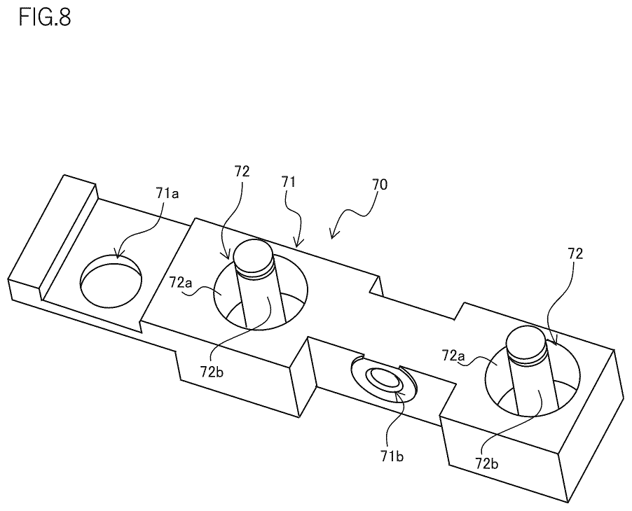

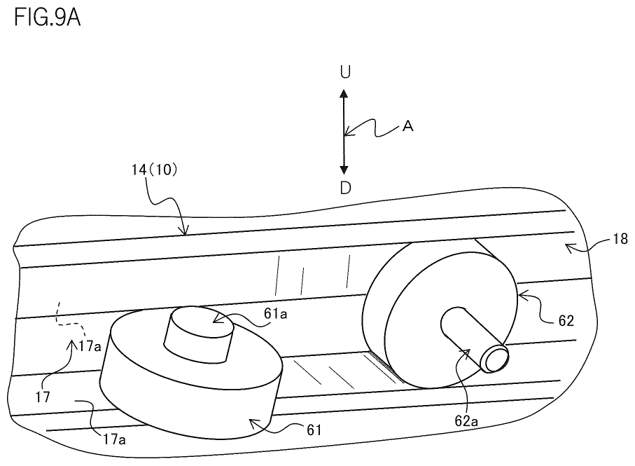

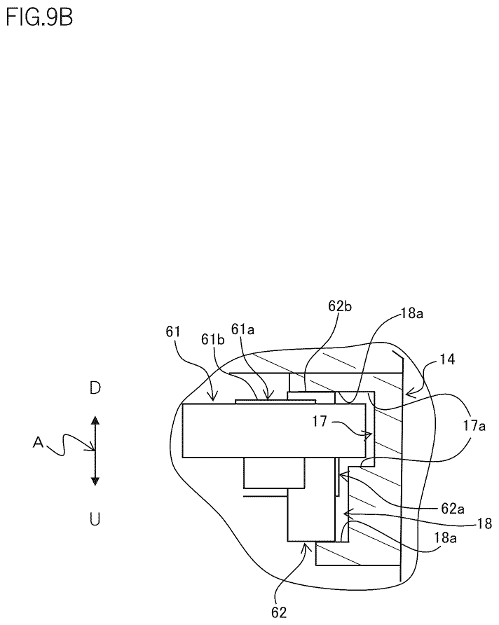

FIG. 1 is a schematic structure diagram of a substrate processing apparatus 100 according to an embodiment. FIG. 2A is a perspective view of a vacuum valve 1 according to the embodiment viewed from an upstream side. FIG. 2B is a perspective view of the vacuum valve 1 according to the embodiment viewed from a downstream side. FIG. 3 is a perspective sectional view of a portion near a first radial bearing 61 of the vacuum valve 1. FIG. 4 is a drawing of the vacuum valve 1 partially extracted. FIG. 5 is a sectional view of a portion near an air cylinder 19b of the vacuum valve 1 depicted in FIG. 4. FIG. 6 is a drawing of the vacuum valve 1 partially extracted with a shutter 40 being in a closed state. FIG. 7 is an enlarged view of a shutter guide mechanism 60 depicted in FIG. 6. FIG. 8 is a perspective view of a holder 70. FIG. 9A is a drawing for describing a guide relation between the first radial bearing 61 and a second radial bearing 62, depicting a perspective view of a first guide groove 17 and a second guide groove 18. FIG. 9B is a drawing for describing a guide relation between the first radial bearing 61 and the second radial bearing 62, depicting a sectional view of the first guide groove 17 and the second guide groove 18.

The vacuum valve 1 according to the embodiment of the present invention is used as a valve in an exhaust system of the substrate processing apparatus 100 such as, for example, a semiconductor wafer, liquid-crystal substrate, or substrate for a solar cell panel, and a circular gate valve is used in the present embodiment.

This vacuum valve 1 is interposed between an exhaust connecting portion 112 of a chamber 110 (hereinafter referred to as a process chamber), which is a vacuum processing chamber for processing a substrate by using gas, and an exhaust path 220 connected to a vacuum pump 210. By opening and closing a flow path port 32 with a shutter 40, the exhaust path 220 is brought into or out of communication.

### Regarding Substrate Processing Apparatus 100

The substrate processing apparatus 100 has, as depicted in FIG. 1, a process chamber 110, a gas introduction system, not depicted, for introducing gas necessary for processing on a substrate into the process chamber 110, an exhaust system 200 that exhausts gas in the process chamber 110, and a control apparatus 300 that controls each unit of the substrate processing apparatus 100.

While the present embodiment exemplarily describes the substrate processing apparatus 100 including one process chamber 110, the substrate processing apparatus 100 may include a plurality of process chambers 110, or another component such as a vacuum preparatory chamber may be added.

### Regarding Process Chamber 110

The process chamber 110 is configured so as to allow its inner pressure to be decreased to an inner vacuum pressure and allow gas to be introduced thereinto.

The process chamber 110 is formed in a box shape made of metal, for example, Al (aluminum), Y (yttrium), or the like, and has a chamber main body 111 into and out from which a substrate is delivered, a gas introduction connecting portion, not depicted, connected to the gas introduction system, and an exhaust connecting portion 112 connected to the exhaust system 200.

The exhaust connecting portion 112 forms a flange portion connected to a chamber-side connection flange 20 of the vacuum valve 1.

### Regarding Exhaust System 200

The exhaust system 200 has the vacuum pump 210, and the vacuum valve 1 interposed between the exhaust connecting portion 112 of the process chamber 110 and an exhaust path 220 connected to the vacuum pump 210.

### Regarding Vacuum Valve 1

AAs depicted in FIG. 3 and FIG. 6, a circular gate valve is used as the vacuum valve 1 in this embodiment.

The vacuum valve 1 has a valve housing 10 accommodating each portion of the valve, the chamber-side connection flange 20 connectably provided to the exhaust connecting portion 112 of the process chamber 110, an exhaust-side connection flange 30 connectably provided to the exhaust path 220 linked to the vacuum pump 210, a shutter 40 movably provided in the valve housing 10 in parallel to the flow path port 32, a shutter ring 50 provided in the valve housing 10 so as to be able to advance and retreat along a flow path direction, and a shutter guide mechanism 60 guiding the movement of the shutter 40 in the valve housing 10.

### Regarding Valve Housing 10 of Vacuum Valve 1

The valve housing 10 has an accommodation space where each portion of the vacuum valve 1 is accommodated, the accommodation space being formed in a box shape having a plurality of surfaces.

Specifically, the valve housing 10 has an upstream wall 11 and a downstream wall 12 that are walls opposed to the flow path direction and have formed therein flow path ports 22 and 32 on upstream and downstream sides, respectively, and paired side walls 13 and 14 provided to both side portions of the upstream wall 11 and the downstream wall 12. The valve housing 10 has a front wall 15 and a back wall 16 opposed in a direction in which the shutter 40 moves in parallel to the flow path port 32. This valve housing 10 has, as depicted in FIG. 6, a driving arm 19 movably accommodated in a space where the shutter 40 retreated from the flow path port 32 is arranged, that is, a space for accommodating the shutter 40 in an open state.

Also in the valve housing 10, as depicted in FIGS. 9A and 9B, a first guide groove 17 that guides a first radial bearing 61 described further below in parallel to the flow path port 32 is formed.

This first guide groove 17 is linearly formed in inner wall surfaces of the paired side walls 13 and 14 in parallel to the flow path port 32.

Also, the width of the first guide groove 17 is set slightly larger than the width of the first radial bearing 61 in the axial direction.

The first radial bearing 61 is set so as to be guided by side surfaces 17a, 17a of the first guide groove 17 opposed to each other in the axial direction of the first radial bearing 61 in parallel to the flow path port 32.

Also, in the valve housing 10, a second guide groove 18 that guides a second radial bearing 62 described further below in parallel to the flow path port 32 is linearly formed in parallel to the flow path port 32.

This second guide groove 18 is linearly formed in inner wall surfaces of the paired side walls 13 and 14 in parallel to the flow path port 32.

Also, the width of the second guide groove 18 is set slightly larger than the outer diameter of the second radial bearing 62.

The second radial bearing 62 is set so as to be guided by side surfaces 18a, 18b of the second guide groove 18 opposed to each other in a radial direction of the second radial bearing 62 in parallel to the flow path port 32.

As depicted in FIG. 9B, in the present embodiment, the amount of play of the second radial bearing 62 with respect to the second guide groove 18 in the radial direction is set smaller than the amount of play of the first radial bearing 61 in the axial direction with respect to the first guide groove 17.

The first radial bearing 61 and the second radial bearing 62 are attached to a holder 70 described further below to move in conjunction with the holder 70. Thus, with the second radial bearing 62 restricting the amount of movement of the first radial bearing 61 in the axial direction by the second guide groove 18, it is possible to inhibit the first radial bearing 61 from making contact with the side surface of the first guide groove 17.

Also, in the present embodiment, the amount of play of the second radial bearing 62 with respect to the second guide groove 18 in the radial direction is set smaller than the amount of play of the first radial bearing 61 in the axial direction with respect to the first guide groove 17.

The first radial bearing 61 and the second radial bearing 62 are attached to a holder 70 described further below to move in conjunction with the holder 70. Thus, with the second radial bearing 62 restricting the amount of movement of the first radial bearing 61 in the axial direction by the second guide groove 18, it is possible to inhibit the first radial bearing 61 from making contact with the side surface of the first guide groove 17.

Also, the amount of play of the first radial bearing 61 with respect to the first guide groove 17 in the radial direction is set smaller than the amount of play of the second radial bearing 62 in the axial direction with respect to the second guide groove 18. The first radial bearing 61 and the second radial bearing 62 are attached to a holder 70 described further below to move in conjunction with the holder 70. Thus, the first radial bearing 61 restricts the amount of movement of the second radial bearing 62 in the axial direction by the first guide groove 17. With this, it is possible to inhibit the second radial bearing 62 from making contact with the second guide groove 18 in the axial direction.

Note in this embodiment that the first guide groove 17 and the second guide groove 18 mutually share relevant one of the side surfaces 17a and 18a.

### Regarding Chamber-Side Connection Flange 20 of Vacuum Valve 1

The chamber-side connection flange 20 has, as depicted in FIG. 3, an annular protruding portion 21 fitted in an inner diameter side of a flow path port 11b formed in an upstream wall 11, and is coupled to the valve housing 10.

This annular protruding portion 21 has an end face 21a aligned with an inner wall surface 11a of the upstream wall 11.

That is, in the present embodiment, the end face 21a of the chamber-side connection flange 20 forms part of the inner wall surface 11a of the upstream wall 11 of the valve housing 10.

Also, an inner circumferential surface 20a of the chamber-side connection flange 20 forms an inner circumferential surface of the flow path port 11b. Thus, in the present embodiment, the flow path port 22 is formed of the chamber-side connection flange 20 on the upstream side of the valve housing 10.

Also, inside the chamber-side connection flange 20, as depicted in FIG. 4, a plurality of air cylinders 19b are arranged along a circumferential direction in a distributed manner. By the plurality of these air cylinders 19b, the shutter ring 50 is pushed out, with its tilt suppressed, to the downstream direction.

The chamber-side connection flange 20 has formed therein an air supply hole 23 for accepting air from an air supply source, and can supply driving air to each air cylinder 19b through a flow path 24 formed inside.

More specifically, as depicted in FIG. 5, an annular air chamber 25 is formed inside the chamber-side connection flange 20, and the air cylinders 19b are arranged along the circumferential direction of an annular member 26 that sections this air chamber 25.

When air is supplied to the air chamber 25 from the air supply source through the flow path 24, the annular member 26 moves toward the downstream direction. Thus, the plurality of air cylinders 19b together with the annular member 26 push the shutter ring 50 out to the downstream direction.

While a case is exemplarily described in the present embodiment in which the chamber-side connection flange 20 is configured of one member, the chamber-side connection flange 20 may be configured of a plurality of members for ease of assembly.

### Regarding Exhaust-Side Connection Flange 30 of Vacuum Valve 1

The exhaust-side connection flange 30 has, as depicted in FIG. 3, an annular protruding portion 31 fitted in an inner diameter side of a flow path port 12b formed in a downstream wall 12, and is coupled to the valve housing 10.

This annular protruding portion 31 has an end face 31a aligned with an inner wall surface 12a of the downstream wall 12.

That is, in the present embodiment, the end face 31a of the exhaust-side connection flange 30 forms part of the inner wall surface 12a of the downstream wall 12 of the valve housing 10.

Also, an inner circumferential surface 30a of the exhaust-side connection flange 30 forms an inner circumferential surface of the flow path port 12b. Thus, in the present embodiment, the flow path port 32 is formed of the exhaust-side connection flange 30 on the downstream side of the valve housing 10.

### Regarding Shutter of Vacuum Valve 1

The shutter 40 is, as depicted in FIG. 6, a rectangular plate-shaped member having a size capable of closing at least the flow path port 32, and has one end portion coupled to the driving arm 19 that moves the shutter 40 in parallel to the flow path port 32.

Also, the shutter 40 has, as depicted in FIG. 6 and FIG. 7, a notch portion 41 having a portion overlapping the holder 70 notched when viewed from a front side oriented to a flow path direction A.

The holder 70 of the shutter guide mechanism 60 is configured not to interfere with the shutter 40 in the flow path direction A through the notch portion 41.

### Regarding Shutter Ring 50 of Vacuum Valve 1

The shutter ring 50 is provided in the valve housing 10 so as to be able to advance and retreat along the flow path direction A. When the shutter 40 is at an open position, the shutter ring 50 causes a tip surface 52a to abut on the inner wall surface 12a near the flow path port 32 of the valve housing 10 to hermetically form a flow path connected to the flow path port 32. Also, when the shutter 40 is at a closed position, the shutter ring 50 presses the shutter 40 with the tip surface 52a to the inner wall surface 12a to hermetically close the flow path port 32.

When the shutter 40 is in an open state, the shutter ring 50 causes the tip surface 52a to abut on the inner wall surface 12a of the downstream wall 12 of the valve housing 10, more specifically, the inner wall surface 12a of the downstream wall 12 including the end face 31a of the exhaust-side connection flange 30, to hermetically form a flow path connected to the flow path port 32. Also, when the shutter 40 is in a closed state, the shutter ring 50 presses the shutter 40 with the tip surface 52a to the inner wall surface 12a of the downstream wall 12, more specifically, the inner wall surface 12a of the downstream wall 12 including the end face 31a of the exhaust-side connection flange 30, to hermetically close the flow path port 32.

This shutter ring 50 has, as depicted in FIG. 3 and FIG. 6, a sliding cylinder portion 51 slidably fitted in the inner circumferential surface 20a of the chamber-side connection flange 20 and a flange portion 52 formed in a flange-like configuration at the tip of this sliding cylinder portion 51 to cause the tip surface 52a to abut on the inner wall surface 12a of the downstream wall 12 of the valve housing 10 or to press the shutter 40.

As described above, through the flow path port 22 formed by the chamber-side connection flange 20 inside the flow path port 11b of the upstream wall 11, the sliding cylinder portion 51 is slidably fitted in the inner circumferential surface 20a of the chamber-side connection flange 20.

That is, the shutter ring 50 is connected to the chamber-side connection flange 20 so as to be able to advance and retreat in the downstream direction.

Also, the tip surface 52a of the flange portion 52 is provided with an annular seal member 53 as depicted in FIG. 3 and FIG. 4 to take measures against counterpressure.

For example, when the downstream side becomes at atmospheric pressure with respect to the shutter 40 in a closed state to cause the upstream side to become at negative pressure with respect to the shutter 40, the shutter 40 is pushed by a differential pressure to a process chamber 110 side to go away from the exhaust-side connection flange 30, but the shutter 40 makes contact with the annular seal member 53 provided at the tip surface 52a of the shutter ring 50 to allow sealability to be kept.

### Regarding Shutter Guide Mechanism 60

The shutter guide mechanism 60 has, as depicted in FIG. 7, the first radial bearing 61, the second radial bearing 62, a spring member 63 as an elastic member, a holder 70, and a fixing member 80. The first radial bearing 61, the second radial bearing 62, and the spring member 63 are attached to the holder 70. The holder 70 is provided at each of the four corners of the shutter 40 via the bridge-shaped fixing member 80.

### Regarding First Radial Bearing 61

The first radial bearing 61 uses a known roll bearing for supporting a force in a direction orthogonal to the axis.

The first radial bearing 61 is rotatably provided about the first rotating shaft 61a substantially in parallel to the flow path direction A, and rotates along the first guide groove 17 provided in the valve housing 10 in parallel to the flow path port 32.

### Regarding Second Radial Bearing 62

As with the first radial bearing 61, the second radial bearing 62 uses a known roll bearing for supporting a force in a direction orthogonal to the axis.

The second radial bearing 62 is rotatably provided about the second rotating shaft 62a substantially orthogonal to the flow path direction A, and has its outer circumferential surface 62b provided as arranged closer to the flow path port 32 side than the tip surface 61b of the first rotating shaft 61a of the first radial bearing 61.

The second radial bearing 62 rotates along the second guide groove 18 (refer to FIG. 9) provided in the valve housing 10 in parallel to the flow path port 32.

### Regarding Spring Member 63

When the second radial bearing 62 receives a load toward the inside of the valve housing 10 in the flow path direction A via the inner wall surface 12a near the flow path port 32, the spring member 63 exerts a spring-back force on the second radial bearing 62 toward the inner wall surface 12a.

In this embodiment, while the spring member 63 is used as an elastic member, another elastic member such as a plate spring may be used to exert a similar spring-back force.

### Regarding Holder 70

The holder 70 forms a block shape as depicted in FIG. 8, and has attached thereto the first radial bearing 61, the second radial bearing 62, and the spring member 63.

In the holder 70, a block-shaped holder main body 71 in a substantially rectangular parallelepiped shape is provided with a first rotating shaft attachment portion 71a to which the first rotating shaft 61a is to be attached, a second rotating shaft attachment portion 71b to which the second rotating shaft 62a is to be attached, and spring retaining accommodation portions 72 at two locations, each portion being for accommodating the spring member 63 so as to be able to compress the spring member 63. More specifically, from one end portion to the other end portion in the longitudinal direction of the holder main body 71, the first rotating shaft attachment portion 71a, the spring retaining accommodation portion 72, the second rotating shaft attachment portion 71b, and the spring retaining accommodation portion 72 are provided. The first rotating shaft attachment portion 71a and the spring retaining accommodation portions 72 at two locations are provided on surfaces oriented to the same direction. The second rotating shaft attachment portion 71b is provided on a surface oriented to a direction orthogonal to the surfaces where first rotating shaft attachment portion 71a and the spring retaining accommodation portions 72 at two locations are provided.

Thus, when the first rotating shaft 61a attached to the first rotating shaft attachment portion 71a is arranged in parallel to the flow path direction A, the second rotating shaft 62a attached to the second rotating shaft attachment portion 71b is oriented to a direction substantially orthogonal to the flow path direction A.

The first rotating shaft attachment portion 71a forms a hole where the first rotating shaft 61a is inserted, and fixes the first rotating shaft 61a by using a stopper member 71aa such as a so-called snap ring.

The second rotating shaft attachment portion 71b is a hole for fixing an end portion of the second rotating shaft 62a in a direction orthogonal to the first rotating shaft 61a

The spring retaining accommodation portion 72 has an accommodation recessed portion 72a formed in a circular section corresponding to the contour shape of the cross-sectional surface of the spring member 63 to accommodate the spring member 63 and a support connection shaft portion 72b connected to the fixing member 80 while supporting the spring member 63 so as to be able to compress the spring member 63.

The support connection shaft portion 72b penetrates through the center of the spring member 63 from the center position of the bottom surface of the accommodation recessed portion 72a, and has its tip portion penetrating through the fixing member 80 to be connected to the fixing member 80 by using a stopper member 72bb such as a snap ring.

A cylindrical retaining member not depicted may be provided to the outer circumference of the support connection shaft portion 72b and the spring member 63 may be attached to the support connection shaft portion 72b.

This spring retaining accommodation portion 72 is provided at each of two locations for one holder 70 so that the spring members 63 are provided at positions that are symmetrical with respect to the second rotating shaft 62a.

In this manner, by providing the spring member 63 at each of two locations that are symmetrical with respect to the second rotating shaft 62a, it is possible to arrange each of the two spring members 63 and the second radial bearing 62 so as to equalize distances therebetween. Thus, even if the positions of the second radial bearing 62 and the load axis are away from each other, a load in the radial direction to be added to the second radial bearing 62 by spring-back forces of the two spring members 63 can inhibit the second radial bearing 62 from rotating. As a result, as the second radial bearing 62 receives a load from the inner wall surface 12a of the valve housing 10 in a balanced manner, the shutter 40 can be actuated toward the inside of the valve housing 10.

This effect can be more enhanced if the second radial bearing 62 and the spring member 63 are arranged as closely together as possible.

### Regarding Control Apparatus 300

The control apparatus 300 is implemented by, for example, a microcomputer, and has a controller not depicted including a CPU (Central Processing Unit), ROM (Read Only Memory), RAM (Random Access Memory), and so forth to control each portion of the substrate processing apparatus 100, a user interface not depicted implemented by a display or the like, and a storage unit not depicted having various programs such as a control program stored therein.

The control apparatus 300 controls the vacuum valve 1 and so forth based on the control program and so forth stored in the storage unit.

The control apparatus 300 is, as depicted in FIG. 1, connected to various driving systems of the process chamber 110. Also, the control apparatus 300 is connected via a driver to a drive motor 19a for driving the driving arm 19 of the shutter 40 of the vacuum valve 1, an air compressor 19c for supplying driving air to the plurality of air cylinders 19b for moving the shutter ring 50, and a motor 210a of the vacuum pump 210, thereby controlling these units.

### Regarding Operation of Vacuum Valve 1 in Processing on Substrate

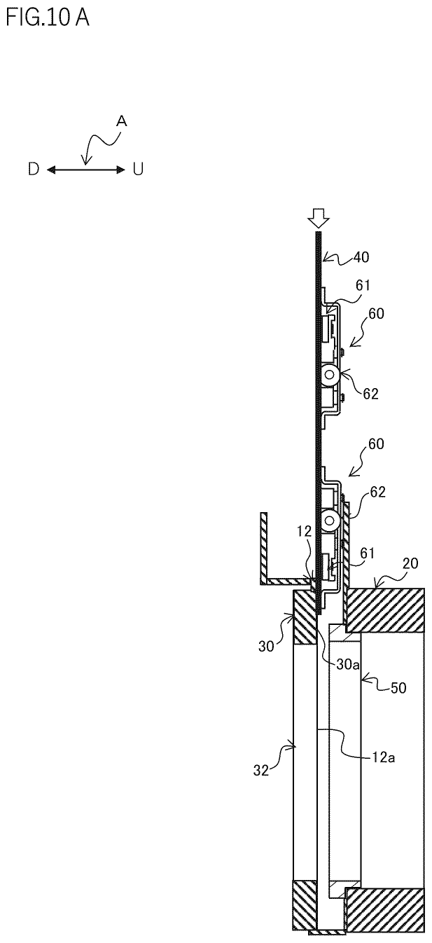

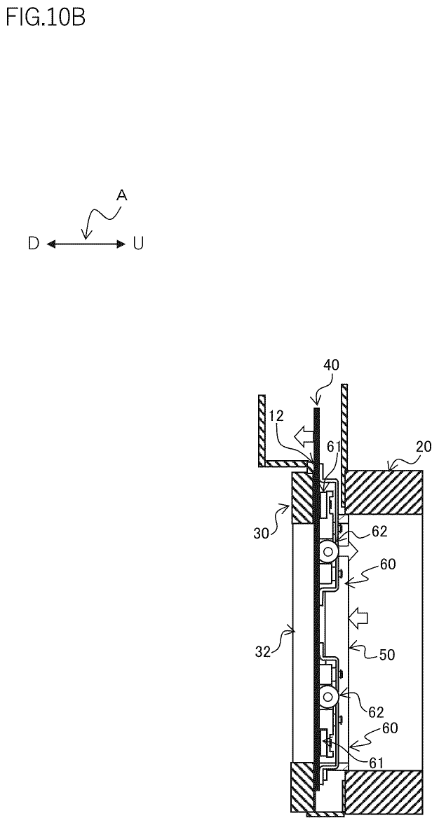

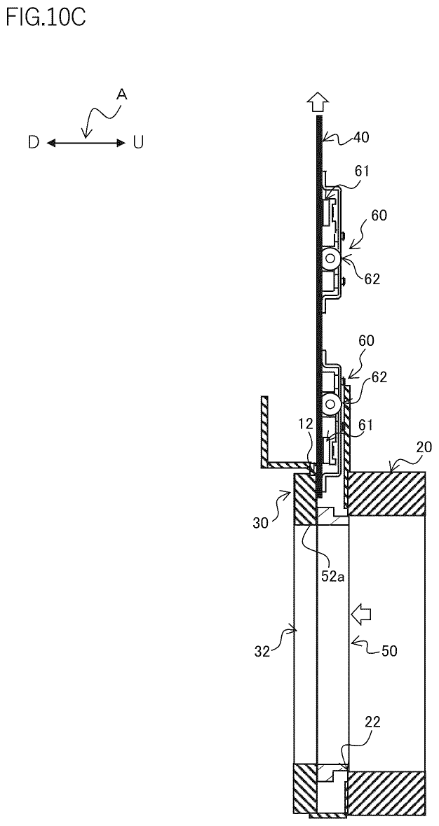

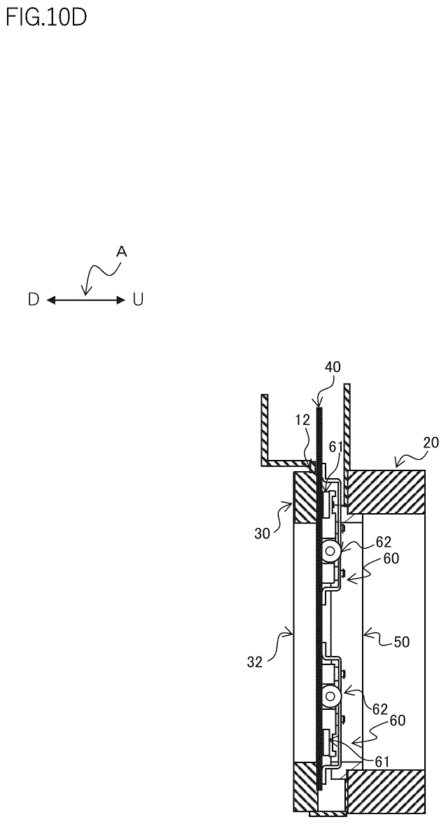

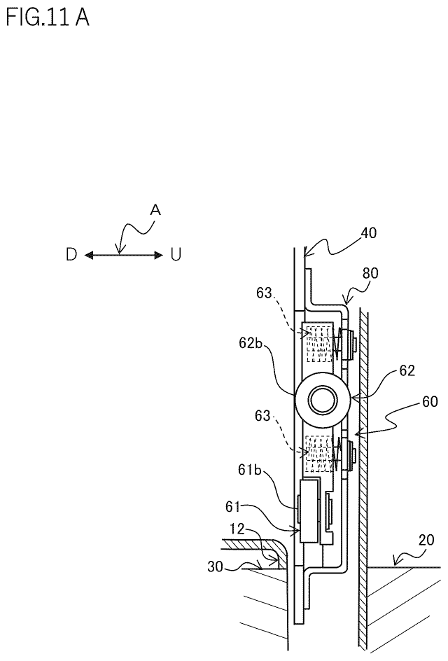

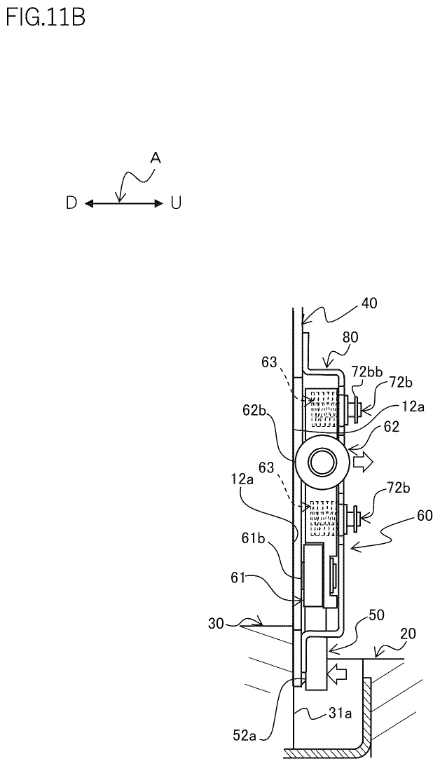

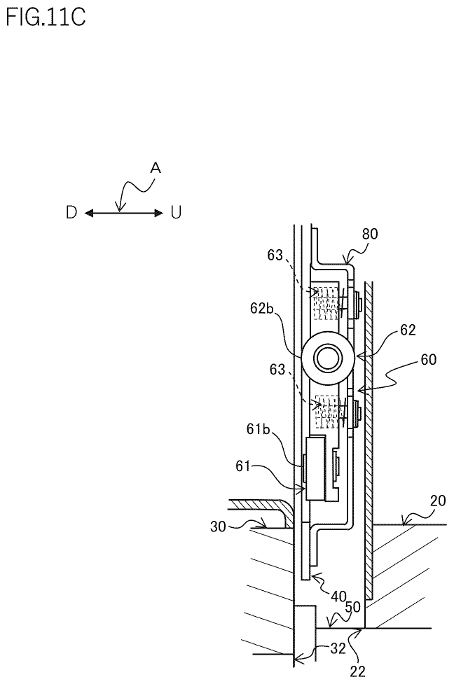

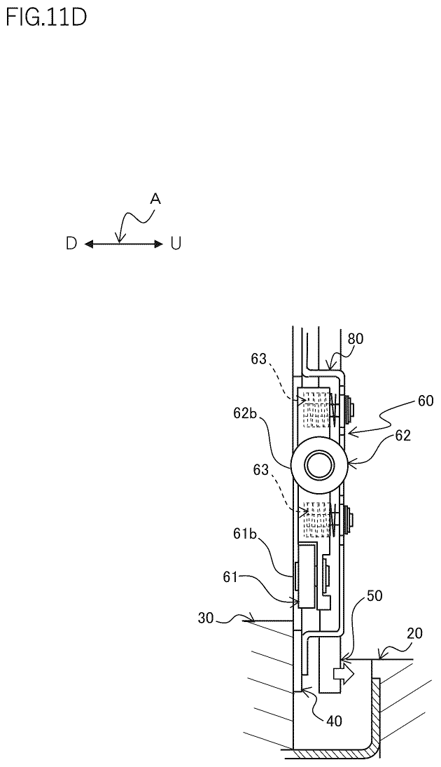

Next, the operation of the vacuum valve 1 in processing on a substrate is described by using FIG. 10A to FIG. 10D and FIG. 11A to FIG. 11D.

FIG. 10A to FIG. 10D are drawings for describing opening/closing operation of the shutter 40. FIG. 11A to FIG. 11D are enlarged views of the shutter guide mechanism 60 on the lower side depicted in FIG. 10A to FIG. 10D.

Here, in the vacuum valve 1, before the processing on the substrate starts, as depicted in FIG. 10A and FIG. 11A, the shutter 40 and the shutter ring 50 are in an open state.

In this state, the shutter 40 is arranged at an open position not interfering with the flow path port of the downstream wall 12, more specifically, the flow path port 32 formed by the exhaust-side connection flange 30.

Also, when the shutter 40 moves in parallel to the flow path port 32 from the open position toward a position opposed to the flow path port 32, the shutter ring 50 is arranged as being away from the flow path port 32 so as not to interfere with the shutter 40.

By using the vacuum pump 210 in the state depicted in FIG. 10A, the evacuation of the inside of the process chamber 110 is performed.

When the evacuation of the process chamber 110 is completed, in the vacuum valve 1, as depicted in FIG. 10B and FIG. 11B, the shutter 40 is moved to a closed position opposed to the flow path port 32.

First, the shutter 40 moves by the above-described driving arm 19 in parallel to the flow path port 32 from the open position to the position opposed to the flow path port 32.

When the shutter 40 moves in parallel to the flow path port 32 from the open position to the position opposed to the flow path port 32, the first radial bearing 61 of the shutter guide mechanism 60 is guided by the above-described first guide groove 17, and the second radial bearing 62 is guided by the above-described second guide groove 18. With this, the shitter 40 moves in parallel to the flow path port 32.

Here, since the movement of the first radial bearing 61 in the axial direction is restricted by the second radial bearing 62, the first radial bearing 61 does not make contact with the side surfaces 17a, 17a of the first guide groove 17 irrespective of whether the vacuum valve 1 is in vertical or horizontal orientation installation.

As depicted in FIG. 10B, when the shutter 40 moves to the position opposed to the flow path port 32, the shutter ring 50 presses the shutter 40 with the tip surface 52a toward the inner wall surface 12a of the downstream wall 12, more specifically, the inner wall surface 12a of the downstream wall 12 including the end face 31a of the exhaust-side connection flange 30 (refer to FIG. 11B).

When the shutter ring 50 presses the shutter 40 toward the inner wall surface 12a of the downstream wall 12, the second radial bearing 62 with its outer circumferential surface 62b arranged closer to the flow path port 32 side than the tip surface 61b of the first rotating shaft 61a of the first radial bearing 61 has its outer circumferential surface 62b pushed onto the inner wall surface 12a of the downstream wall 12.

Then, by receiving a load toward the inside of the valve housing 10 in the flow path direction A, the second radial bearing 62 moves toward the inside of the valve housing 10.

With the second radial bearing 62 moving toward the inside of the valve housing 10, the holder 70 having this second radial bearing 62 attached thereto moves toward the inside of the valve housing 10.

When the holder 70 moves to the inside of the valve housing 10, as depicted in FIG. 11B, the support connection shaft portion 72b of the holder 70 is pushed out to an inner side of the valve housing 10 with respect to the fixing member 80. With two spring members 63 accommodated in the holder 70 being compressed, a spring-back force pushing the second radial bearing 62 back to the flow path port 32 side is exerted on the second radial bearing 62.

Thus, when the shutter 40 is pressed by the shutter ring 50 to the inner wall surface 12a of the downstream wall 12, the second radial bearing 62 receives the load applied in the axial direction of the first radial bearing 61 in the radial direction of the second radial bearing 62 while using the spring-back force by the spring members 63.

When the shutter 40 pressed by the shutter ring 50 moves to a position of abutting on the inner wall surface 12a of the downstream wall 12 as depicted in FIG. 10B, the flow path port 32 is hermetically closed by the shutter 40.

After the flow path port 32 is hermetically closed by the shutter 40 in this manner, a substrate is delivered to the inside of the process chamber 110.

After the substrate is delivered to the inside of the process chamber 110, as depicted in FIG. 10C and FIG. 11C, the shutter 40 moves to an open position and the shutter ring 50 is moved to a closed position, thereby hermetically forming a flow path connected to the flow path port 32.

More specifically, the shutter 40 is arranged at the open position not interfering with the flow path port 32, and the shutter ring 50 is pushed out to a downstream side by the plurality of air cylinders 19b provided to the chamber-side connection flanger 20.

Then, the shutter ring 50 pushed out to the downstream side causes the tip surface 52a to abut on the inner wall surface of the valve housing 10, more specifically, the inner wall surface 12a of the valve housing 10 including the end face 31 a of the exhaust-side connection flange 30, to hermetically form a flow path connected to the flow path port 32.

In other words, the flow path port 32 on the downstream side formed by the exhaust-side connection flange 30 and the flow path port 22 on the upstream side formed by the chamber-side connection flange 20 are connected by a hermetical flow path isolated from other areas within the valve housing 10 by the shutter ring 50.

When the shutter 40 moves to the open position, the shutter 40 is released from the pressing force by the shutter ring 50 toward the inner wall surface 12a of the downstream wall 12, and the spring member 63 is elastically restored from a compressed state, thereby causing the shutter 40 to move to a position away from the inner wall surface 12a.

After the flow path ports 31 and 22 on the upstream side and the downstream side of the valve housing 10 are connected by the shutter ring 50 via a hermetical flow path, the substrate processing apparatus 100 starts processing on a substrate not depicted inside the process chamber 110 by using gas introduced from the gas introduction system.

When the processing on the substrate inside the process chamber 110 is completed, as depicted in FIG. 10D and FIG. 11D, the shutter ring 50 is moved to an open position, and then the shutter 40 is moved to a closed position.

Then, as depicted in FIG. 10B, the shutter ring 50 presses the shutter 40 with the tip surface 52a toward the inner wall surface 12a of the downstream wall 12, more specifically, the inner wall surface 12a of the downstream wall 12 including the end face 30a of the exhaust-side connection flange 30 to hermetically close the flow path port 32. Then, the substrate processing apparatus 100 delivers the substrate outside the process chamber 110 to complete the processing on the substrate.

### Effects of Embodiment

As has been described in the foregoing, according to the vacuum valve 1 of the embodiment, by the first radial bearing 61 that rotates along the first guide groove 17 provided in the valve housing 10 in parallel to the flow path port 32 on the downstream side in the flow path direction A formed in the valve housing 10, the shutter 40 is movably guided between a closed position opposed to the flow path port 32 in parallel to the flow path port 32 and an open position that opens the front of the flow path port 32. Also, by the second radial bearing, the load of the first radial bearing 61 in the axial direction is received via the inner wall surface 12a of the valve housing 10 near the flow path port 32 as a load toward the inside of the valve housing 10 in the flow path direction A. Also, the second radial bearing 62 receives the load of the first radial bearing 61 in a direction of the first rotating shaft 61a by using the spring-back force by the spring member 63 in the radial direction.

Thus, according to the vacuum valve 1 of the embodiment, as the radial bearings 61 and 62 capable of supporting both vertical and horizontal orientation installations are applied as bearings for guiding the movement of the shutter 40, the first radial bearing 61 is prevented from being damaged by the load in the direction of the first rotating shaft 61a. As a result, both vertical and horizontal orientation installations can be supported, and durability of the movement guide mechanism of the shutter 40 can be improved.

Also, according to the vacuum valve 1 of the embodiment, the vacuum valve 1 has the holder 70 having the first radial bearing 61, the second radial bearing 62, and the elastic member 63 attached thereto. With the holder 70 being coupled to the shutter 40 so as to be able to elastically advance and retreat via the spring member 63 in the flow path direction A, the first radial bearing 61 moves together with the second radial bearing 62 attached to the holder 70 in the flow path direction A.

Furthermore, the second radial bearing 62 is arranged to a flow path port 32 side with respect to the first radial bearing 61 and uses a spring-back force by the spring member 63 to restrict the amount of movement in the flow path direction A.

Thus, the position of the first radial bearing 61 in the flow path direction A can be stabilized, contact with the side surfaces of the first guide groove 17 can be suppressed, and durability can be improved.

The first radial bearing 61, the second radial bearing 62, and the spring member 63 can be assembled to the shutter 40 in units of the holder 70, and assemblability can be improved.

Furthermore, according to the vacuum valve 1 of the embodiment, the spring member 63 is provided at each of positions that are symmetric with respect to the second rotating shaft 62a. Thus, the load in the radial direction to be added to the second radial bearing 62 by spring-back forces of the two spring members 63 can inhibit the second radial bearing 62 from rotating. As a result, the second radial bearing 62 receives the load from the inner wall surface 12a of the valve housing 10 in a balanced manner, and can stably actuate the shutter 40 toward the inside of the valve housing 10.

According to the vacuum valve 1 of the embodiment, the shutter 40 has a substantially rectangular shape, and the holder 70 is provided at each of portions near the four corners of the shutter 40. With this, by the first radial bearing 61 and the second radial bearing 62 provided at the four corners together with the holder 70, the tilt of the shutter 40 with respect to a posture in parallel to the flow path port 32 is restricted.

Thus, the shutter 40 can be moved to open and close as being kept with a stable posture in parallel to the flow path port 32.

According to the vacuum valve 1 of the embodiment, the valve housing 10 has formed therein the first guide groove 17 that guides the first radial bearing 61 in parallel to the flow path port 32 and the second guide groove 18 that guides the second radial bearing 62 in parallel to the flow path port 32. The first guide groove 17 and the second guide groove 18 have an amount of play with respect to the first radial bearing 61 and an amount of play with respect to the second radial bearing 62, respectively, that are adjusted so as to inhibit contact of the first radial bearing 61 with a side surface of the first guide groove 17 in a direction of the first rotating shaft 61a.

With this, even if the vacuum valve 1 is used for both vertical and horizontal orientation installations, the first radial bearing 61 is prevented from moving in the axial direction to make contact with the side surface 17a of the first guide groove 17 and, as a result, durability of the first radial bearing 17 can be improved.

According to the vacuum valve 1 of the embodiment, the vacuum valve 1 is a circular gate valve. Thus, with a compact and simple structure, the shutter 40 can be guided by the first radial bearing 61 and the second radial bearing 62 to open and close the circular flow path port 32.

Also, according to the substrate processing apparatus 100 of the embodiment, the vacuum valve 1 is interposed between the exhaust connecting portion 112 of the process chamber 110 that processes a substrate and the exhaust path 220 connected to the vacuum pump 210. With this, the effects similar to those by the vacuum valve 1 described above are exerted.

While the embodiments of the present disclosure have been described above, the present disclosure is not limited to the above-described embodiments, and can be variously changed as long as it does not deviate from the gist of the present disclosure.

In the present embodiment, a case of the vacuum valve 1 is exemplarily described in which the exhaust-side connection flange 30 and the valve housing 10 are separately provided and the shutter 40 or the shutter ring 50 abuts on the inner wall surface 12a of the downstream wall 12 including the end face 31a of the exhaust-side connection flange 30. This is not meant to be restrictive. In the vacuum valve 1, the exhaust-side connection flange 30 and the valve housing 10 may be integrally provided, and the shutter 40 or the shutter ring 50 may abut on the inner wall surface of the valve housing 10 integrated with the exhaust-side connection flange 30. Also, in the vacuum valve 1, with the surface of the exhaust-side connection flange 30 on the upstream side not exposed to an inner wall surface side of the valve housing 10, only the inner wall surface of the valve housing 10 may abut on the shutter 40 or the shutter ring 50.

Also, in the present embodiment, a case is exemplarily described in which the shutter ring 50 is driven by the air cylinder 19b. However, the shutter ring 50 may be operated by using another actuator. For example, a motor-driven cylinder may be used to allow the shutter ring to make advancing and retreating movements.

Furthermore, in the present embodiment, a case is exemplarily described in which the vacuum valve 1 is a circular gate valve. However, this is not meant to be restrictive, and the vacuum valve may be another valve as long as it has the shutter 40 provided in the valve housing 10 so as to be movable in parallel to the flow path port 32 formed in the valve housing 10 and the shutter ring 50 that hermetically closes the flow path port 32 by pressing the shutter 40 to the inner wall surface 12a of the valve housing 10 with a tip surface when the shutter 40 is in a closed state, the shutter 40 moving in an L shape to open and close the flow path port.

It should be considered that each of the embodiments disclosed herein is exemplary in all aspects and is not restrictive. The above embodiments may be omitted, replaced, and/or changed in any form without deviating from the scope and the gist of the attached claims.

What is claimed is:

1. A vacuum valve having a shutter provided in a valve housing so as to be movable between a close position and an open position, the close position being opposed in parallel to a flow path port formed in the valve housing on a downstream side in a flow path direction and the open position being for opening a front of the flow path port, and a shutter ring provided in the valve housing so as to be able to advance and retreat along the flow path direction, the shutter ring hermetically closing the flow path port by pressing the shutter to an inner wall surface of the valve housing with a tip surface when the shutter is at the close position, the vacuum valve comprising:
a first radial bearing provided so as to be rotatable about a first rotating shaft substantially parallel to the flow path direction to rotate along a guide groove provided in the valve housing in parallel to the flow path port;
a second radial bearing provided so as to be rotatable about a second rotation shaft substantially orthogonal to the flow path direction and having an outer circumferential surface arranged closer to the flow path port than a tip face of the first rotating shaft of the first radial bearing; and
an elastic member that exerts a spring-back force on the second radial bearing toward the inner wall surface when the second radial bearing receives a load via the inner wall surface of the valve housing near the flow path port toward the inside of the valve housing in the flow path direction.

2. The vacuum valve according to claim 1, further comprising:
a holder having the first radial bearing, the second radial bearing, and the elastic member attached thereto, wherein
the holder is coupled to the shutter so as to be able to elastically advance and retreat via the elastic member in the flow path direction.

3. The vacuum valve according to claim 2, wherein
the elastic member is provided at each of positions that are symmetric with respect to the second rotating shaft.

4. The vacuum valve according to claim 2, wherein
the shutter has a substantially rectangular shape, and
the holder is provided at each of portions near the four corners of the shutter.

5. The vacuum valve according to claim 2, wherein
the valve housing has formed therein a first guide groove being a guide groove that guides the first radial bearing in parallel to the flow path port and a second guide groove that guides the second radial bearing in parallel to the flow path port, and
the first guide groove and the second guide groove have an amount of play with respect to the first radial bearing and an amount of play with respect to the second radial bearing, respectively, that are adjusted so as to inhibit contact of the first radial bearing with a side surface of the first guide groove in a direction of the first rotating shaft.

6. The vacuum valve according to claim 1, wherein
the vacuum valve is a circular gate valve.

7. A substrate processing apparatus, wherein
the vacuum valve according to claim 1 is interposed between an exhaust connecting portion of a chamber that processes a substrate and an exhaust path connected to a vacuum pump.
